(19) United States
(12) Patent Application Publication
(10) Pub. No.: US 2025/0026661 A1
(43) Pub. Date: Jan. 23, 2025

(54) NANOPARTICLE, PREPARATION METHOD THEREFOR, AND LIGHT-EMITTING DIODE

(71) Applicant: TCL TECHNOLOGY GROUP CORPORATION, Huizhou, Guangdong (CN)

(72) Inventor: Hua JIANG, Huizhou, Guangdong (CN)

(73) Assignee: TCL TECHNOLOGY GROUP CORPORATION, Huizhou, Guangdong (CN)

(21) Appl. No.: 18/711,846

(22) PCT Filed: Nov. 1, 2022
(86) PCT No.: PCT/CN2022/129064

§ 371 Date: May 20, 2024

(30) Foreign Application Priority Data
Nov. 19, 2021 (CN) 202111408087.2

(51) Int. Cl. C01G 9/02; B82Y 30/00; B82Y 40/00; C01B 33/12; C09K 11/02; H10K 50/115; H10K 50/15; H10K 50/16; H10K 85/60

(52) U.S. Cl. CPC C01G 9/02; B82Y 30/00; B82Y 40/00; C01B 33/12; C09K 11/02; H10K 50/115; H10K 50/15; H10K 50/16; H10K 85/60; C01P 2004/64

(57) ABSTRACT

A nanoparticle, a preparation method therefor, and a light-emitting diode are disclosed. The nanoparticle provided in the present application includes a zinc oxide nanoparticle as a core, and a silicon dioxide coating layer partially coating the zinc oxide nanoparticle as a shell, such that the nanoparticle has an asymmetric electronic structure, and the interaction of different material interfaces may be reduced, thereby improving the stability and conductivity of the material.

This application claims priority to Chinese Patent Applications No. 202111408087.2, filed on Nov. 19, 2021 and entitled “NANO-PARTICLE, NANO-FILM, LIGHT-EMITTING DIODE AND DISPLAY DEVICE”. The entire disclosures of the above application are incorporated herein by reference.

### TECHNICAL FIELD

The present application relates to the field of display technology, and in particular, to a nanoparticle, a preparation method thereof, and a light-emitting diode.

### BACKGROUND TECHNOLOGY

ZnO nanoparticles have the characteristics of large specific surface area, relatively uniform particle size, and good dispersion, and are one of the best candidate materials for electron transport layers. However, ZnO has extremely high surface activity and may easily adsorb active small molecules in the environment, such as water molecules, oxygen molecules, ethanol molecules, etc. These adsorbed small molecules are difficult to completely remove through an annealing process, and a small amount of remaining small molecules may desorb when the device is powered on for a long time. On the one hand, the desorbed small molecules may become free and active small molecules, causing damage to various functional layers of the device. On the other hand, the desorption of adsorbed small molecules may change an electronic state of a ZnO surface, causing ZnO nanoparticles themselves to be in an unstable state of electrification, affecting an electron transport function of ZnO itself. A current unstable state of ZnO nanoparticles is also reflected in performance results of QLED devices, but the mechanism is not yet clear, this issue is often ignored.

In some research works, zinc oxide with a core-shell structure is still used to improve stability of ZnO nanoparticles, but there is an issue of greatly reduced conductivity.

### SUMMARY OF INVENTION

Therefore, the present application provides a nanoparticle, a preparation method thereof, and a light-emitting diode.

Embodiments of the present application provide a nanoparticle, comprising a zinc oxide nanoparticle and a silicon dioxide coating layer, wherein a surface of the zinc oxide nanoparticle is partially covered with the silicon dioxide coating layer.

Optionally, in some embodiments of the present application, a contact area between the silicon dioxide coating layer and the zinc oxide nanoparticle accounts for 30% to 70% of a surface area of the zinc oxide nanoparticle.

Optionally, in some embodiments of the present application, oxygen atoms of the zinc oxide nanoparticle and oxygen atoms of silicon dioxide in the silicon dioxide coating layer are connected through covalent bonds.

Optionally, in some embodiments of the present application, the zinc oxide nanoparticle comprises a zinc oxide material or a doped zinc oxide material, and a doping element of the doped zinc oxide material comprises any one of Mg, Al, and Ga.

Optionally, in some embodiments of the present application, in the doped zinc oxide material, a molar ratio of the zinc oxide and the doping element is 1:(0.1˜0.3).

Optionally, in some embodiments of the present application, a particle size of the zinc oxide nanoparticle ranges from 3 nm to 5 nm.

Correspondingly, embodiments of the present application further provide a preparation method for a nanoparticle, comprising: providing a nanoparticle having a zinc oxide nanoparticle core and a silicon dioxide coating layer; suspending the nanoparticle having the zinc oxide nanoparticle core and the silicon dioxide coating layer at a junction of an aqueous solution and an oil phase solution; adding an acid etching solution to the aqueous solution, and acid etching to remove the silicon dioxide coating layer in the nanoparticle that is in contact with the aqueous solution to obtain the nanoparticle.

Optionally, in some embodiments of the present application, the preparation method further comprises: suspending the nanoparticle having the zinc oxide nanoparticle core and the silicon dioxide coating layer at the junction of an aqueous phase solution and the oil phase solution, and adding a lipophilic ligand to the oil phase solution.

Optionally, in some embodiments of the present application, the lipophilic ligand contains a lipophilic group, and the lipophilic group comprises any one of a hydrocarbon group having 10 to 20 carbon atoms, a hydrocarbon group containing an aryl, an ester, an ether, an amine, and an amide group, a hydrocarbon group containing double bonds, a polyoxypropylene group, a long-chain perfluoroalkyl group, and a polysiloxane group.

Optionally, in some embodiments of the present application, a carbon chain length of the polyoxypropylene group is 6 to 18;
a carbon chain length of the long-chain perfluoroalkyl group is 6 to 18; and
a carbon chain length of the polysiloxane group is 6 to 18.

Optionally, in some embodiments of the present application, the lipophilic ligand comprises a n-octylamine or an octadecene.

Optionally, in some embodiments of the present application, the acid etching solution comprises a hydrogen peroxide and a hydrofluoric acid.

Optionally, in some embodiments of the present application, a density of the oil phase solution is greater than a density of the aqueous phase solution, and the oil phase solution comprises any one of a chlorobenzene, a nitrobenzene, a chloroform, a carbon tetrachloride, a carbon disulfide, a dimethyl sulfoxide, and a methylene chloride.

Optionally, in some embodiments of the present application, after acid etching to remove the silicon dioxide coating layer in the nanoparticle that is in contact with the aqueous solution, the preparation method for the nanoparticle further comprises: removing the aqueous solution, adding a precipitant for purification, and obtaining the nanoparticle; wherein the precipitant comprises one or more of a n-hexane and a n-heptane.

Correspondingly, embodiments of the present application further provide a light-emitting diode, comprising: an anode, a cathode, and a light-emitting layer arranged between the anode and the cathode, wherein an electron transport layer is further provided between the cathode and the light-emitting layer, a material of the electron transport layer comprises a nano-film, the nano-film comprises a zinc oxide nanoparticle and a silicon dioxide coating layer, and at least part of a surface of the zinc oxide nanoparticle is partially coated with the silicon dioxide coating layer.

Optionally, in some embodiments of the present application, a contact area between the silicon dioxide coating layer and the zinc oxide nanoparticle accounts for 30% to 70% of a surface area of the zinc oxide nanoparticle.

Optionally, in some embodiments of the present application, oxygen atoms of the zinc oxide nanoparticle and oxygen atoms of silicon dioxide in the silicon dioxide coating layer are connected through covalent bonds.

Optionally, in some embodiments of the present application, the zinc oxide nanoparticle comprises a zinc oxide material or a doped zinc oxide material, and a doping element of the doped zinc oxide material comprises any one of Mg, Al, and Ga.

Optionally, in some embodiments of the present application, a particle size of the zinc oxide nanoparticle ranges from 3 nm to 5 nm.

Optionally, in some embodiments of the present application, a thickness of the electron transport layer is 10 nm to 60 nm.

Optionally, in some embodiments of the present application, a light-emitting layer is a quantum dot light-emitting layer, a quantum dot material of the quantum dot light-emitting layer is selected from one or more combinations of CdS, CdSe, CdTe, ZnO, ZnS, ZnSe, ZnTe, GaAs, GaP, GaSb, HgS, HgSe, HgTe, InAs, InP, InSb, AlAs, AlP, CuInS, or CuInSe;
a material of the anode comprises one or more of an indium tin oxide, an indium zinc oxide, Au, Pt, or Si;
a material of the cathode comprises one or more of Al, Ag, Au, or Cu;
the light-emitting diode further comprises a hole injection layer and a hole transport layer provided between the light-emitting layer and the anode, the hole injection layer is located between the hole transport layer and the anode;
a material of the hole injection layer is selected from one or more of PEDOT:PSS, NiO, MoO₃, WO₃, and V₂O₅; and
a material of the hole transport layer is selected from one or more of poly(9,9-dioctylfluorene-CO—N-(4-butylphenyl)diphenylamine), polyvinylcarbazole, poly(N,N′bis(4-butylphenyl)-N,N′-bis(phenyl)benzidine), poly(9,9-dioctylfluorene-co-bis-N,N-phenyl 1,4-phenylenediamine), 4,4′,4″-tris(carbazol-9-yl)triphenylamine, 4,4′-bis(9-carbazole)biphenyl, N,N′-diphenyl-N,N′-bis(3-methylphenyl)-1,1′-biphenyl-4,4′-diamine, N,N′-diphenyl-N,N′-(1-naphthyl)-1,1′-biphenyl-4,4′-diamine.

The nanoparticle proposed in embodiments of this present application use a zinc oxide nanoparticle as a core and a silicon dioxide coating layer partially covering the zinc oxide nanoparticle as a shell. Therefore, the nanoparticle has an asymmetric electronic structure, which may reduce an interaction at an interface of different materials, thereby improving stability and conductivity of the material.

### BRIEF DESCRIPTION OF THE DRAWINGS

In order to explain technical solutions in embodiments of the present application more clearly, drawings needed to be used in the description of the embodiments will be briefly introduced below. Obviously, the drawings in the following description are only some embodiments of the present application. For those skilled in the art, other drawings may also be obtained based on these drawings without exerting creative efforts.

FIG. 1 is a schematic flowchart of a preparation method for a nanoparticle according to an embodiment of the present application.

FIG. 2 is a schematic diagram of a preparation method for a nanoparticle according to another embodiment of the present application.

FIG. 3 is a schematic flowchart of a preparation method for a nanoparticle according to another embodiment of the present application.

FIG. 4 is a schematic diagram of a structure of a quantum dot light-emitting diode.

### DETAILED DESCRIPTION OF THE PREFERRED EMBODIMENTS

The technical solutions in the embodiments of the present application will be clearly and completely described below with reference to the accompanying drawings in the embodiments of the present application. Obviously, the described embodiments are only some of the embodiments of the present application, but not all of the embodiments. Based on the embodiments in this application, all other embodiments obtained by those skilled in the art without creative efforts fall within the scope of protection of this application.

It should be noted that the order of description of the following embodiments does not limit the preferred order of the embodiments. In addition, in the description of this application, the term “including” means “including but not limited to.” Various embodiments of the present application may exist in the form of a range. It should be understood that the description in a range format is merely for convenience and simplicity and should not be construed as a rigid limitation on the scope of the present application. Accordingly, the stated range descriptions should be considered to have specifically disclosed all possible subranges as well as the single values within such ranges. For example, a description of a range from 1 to 6 should be considered to have specifically disclosed subranges, such as from 1 to 3, from 1 to 4, from 1 to 5, from 2 to 4, from 2 to 6, from 3 to 6, etc., and a single number within the stated range, such as 1, 2, 3, 4, 5, and 6, applies regardless of the range. Additionally, whenever a numerical range is stated herein, it is intended to include any cited number (fractional or whole) within the indicated range.

In this application, “one or more” means one or more, and “plurality” means two or more. “One or more”, “at least one of the following” or similar expressions thereof refers to any combination of these items, including any combination of single item or plural item. For example, “at least one of a, b, or c”, or “at least one of a, b, and c” may mean: a, b, c, a-b (That is, a and b), a-c, b-c, or a-b-c, where a, b, and c may be single or multiple respectively.

This application provides a nanoparticle, a preparation method thereof, and a light-emitting diode. Each is explained in detail below. It should be noted that the order of description of the following embodiments does not limit the preferred order of the embodiments.

Embodiments of the present application provide a nanoparticle including a zinc oxide nanoparticle and a silicon dioxide coating layer. A surface of the zinc oxide nanoparticles is partially coated with the silicon dioxide coating layer. The zinc oxide nanoparticle partially coated with a silicon dioxide coating has an asymmetric electronic structure. That is, ZnO is conductive, but SiO2 is not conductive. ZnO is highly active, and SiO2 is low active. This results in an asymmetric distribution of electrons inside the nanoparticle. The conductivity and active transition of film layers used to prepare devices often vary greatly, and chemical reactions (interactions) may also occur between film layers. ZnO conducts electricity, but SiO2 does not conduct electricity. ZnO has high activity, and SiO2 has low activity. This asymmetric feature allows the SiO2 side of the nanoparticle to contact the high-activity film layer, and the ZnO side to contact the low-activity film layer. Single-layer isolation between film layers is achieved through different ligands on both sides of the nanoparticle, thus reducing an interaction at a material interface. This not only ensures stability between film layers (no reaction occurs), but also achieves a smooth transition between the film layers (minimizing impact on the device). However, fully-coated nanoparticle has a symmetrical structure and isotropic ligand, making it difficult to achieve single-layer isolation.

In some embodiments of the present application, a contact area between the silicon dioxide coating layer and the zinc oxide nanoparticle accounts for 50% of a surface area of the zinc oxide nanoparticle. However, because a size of the nanoparticle is not completely uniform, a contact area between the silicon dioxide coating layer and the zinc oxide nanoparticle in the prepared nanoparticle fluctuates between 30% and 70%. TEM (Transmission Electron Microscopy) is used to detect the size of the nanoparticle before and after silicon dioxide coating, and a silicon dioxide coating ratio and distribution may be obtained by counting the particle size ratio.

In some embodiments of the present application, oxygen atoms of the zinc oxide nanoparticle and oxygen atoms of silicon dioxide in the silicon dioxide coating layer are connected through covalent bonds.

In some embodiments of the present application, the zinc oxide nanoparticle comprises a zinc oxide material or a doped zinc oxide material, and a doping element of the doped zinc oxide material include, but are not limited to, Mg, Al or Ga. In the doped zinc oxide material, a molar ratio of the zinc oxide and the doping element is 1:(0.1˜0.3).

In some embodiments of the present application, a particle size range of the zinc oxide nanoparticle may be 3 nm to 5 nm, 3.5 nm to 4.5 nm, or 4 nm.

The nanoparticle provided in examples of this application may be prepared by the following method.

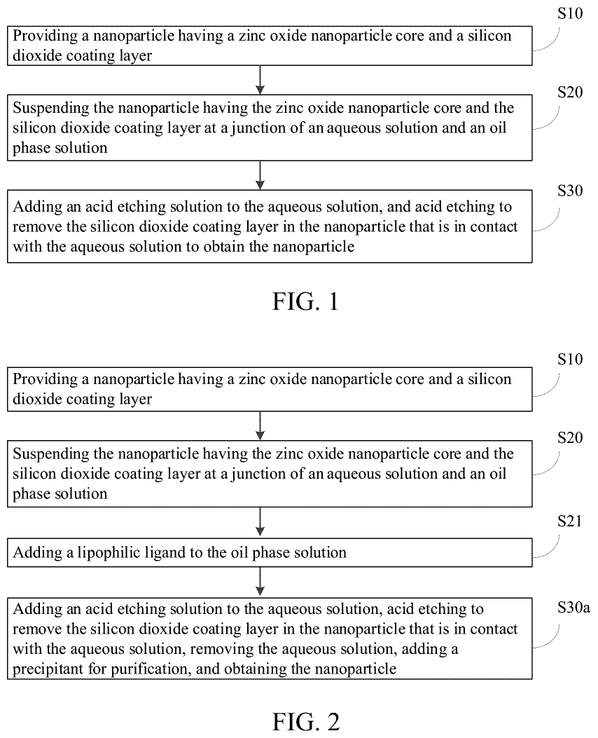

Referring to FIG. 1, an embodiment of the present application further provides a preparation method for a nanoparticle, comprising: S10, providing a nanoparticle having a zinc oxide nanoparticle core and a silicon dioxide coating layer; S20, suspending the nanoparticle having the zinc oxide nanoparticle core and the silicon dioxide coating layer at a junction of an aqueous solution and an oil phase solution; S30, adding an acid etching solution to the aqueous solution, and acid etching to remove the silicon dioxide coating layer in the nanoparticle that is in contact with the aqueous solution to obtain the nanoparticle. An outer surface of the zinc oxide nanoparticle (as the core) of the nanoparticle produced by the method of the embodiment of the present application is partially covered by the silicon dioxide coating layer (as a shell layer).

Referring to FIG. 2, in some embodiments of the present application, after suspending the nanoparticle having the zinc oxide nanoparticle core and the silicon dioxide coating layer at the junction of the aqueous solution and the oil phase solution, the preparation method further comprises: Step S21, adding a lipophilic ligand to the oil phase solution. The lipophilic ligand is used to immobilize suspended nanoparticle.

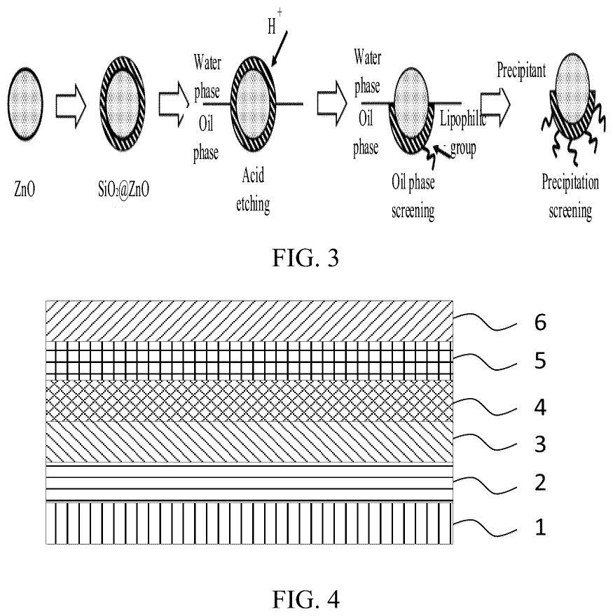

Referring to FIG. 2 and FIG. 3, in some embodiments of the present application, after obtaining the zinc oxide nanoparticle partially coated with silicon dioxide, the preparation method further comprises: removing the aqueous solution, adding a precipitant to purify the zinc oxide nanoparticle partially coated with silicon dioxide. That is, step S30 may include: S30a, adding an acid etching solution to the aqueous solution, acid etching to remove the silicon dioxide coating layer in the nanoparticle that is in contact with the aqueous solution, removing the aqueous solution, adding a precipitant for purification, and obtaining the nanoparticle. As an exemplary embodiment, the precipitant may include, but is not limited to, one or more of n-hexane and n-heptane.

In some embodiments of the present application, the acid etching solution comprises a hydrogen peroxide and a hydrofluoric acid.

In some embodiments of the present application, a density of the oil phase solution is greater than a density of the aqueous phase solution, and the oil phase solution comprises a chlorobenzene, a nitrobenzene, a chloroform, a carbon tetrachloride, a carbon disulfide, a dimethyl sulfoxide, or a methylene chloride.

In some embodiments of the present application, the lipophilic ligand contains a lipophilic group, and the lipophilic group comprises a hydrocarbon group having 10 to 20 carbon atoms, a hydrocarbon group containing an aryl, an ester, an ether, an amine, and an amide group, a hydrocarbon group containing double bonds, a polyoxypropylene group, a long-chain perfluoroalkyl group, or a polysiloxane group. The carbon chain length of polyoxypropylene group, long-chain perfluoroalkyl group, or polysiloxane group is 6 to 18.

In some embodiments of the present application, the lipophilic ligand includes n-octylamine or octadecene.

As an exemplary embodiment, as shown in FIG. 3, the specific preparation method of nanoparticle in this example includes the following steps:
(1) Preparation of zinc oxide nanoparticle: Weigh 5.5 g zinc acetate dihydrate and dissolve it in 150 ml ethanol solution. Heat and stir at 80° C. for 2 hours until acetic acid is completely dissolved. Then place the above solution in a cold water bath. Take 20 ml of 1.75 mol/L potassium hydroxide solution and slowly pour the potassium hydroxide solution into the above solution. When the solution becomes clear, the preparation of ZnO nanoparticle is completed.

In addition to the above methods, other methods may also be used to prepare zinc oxide nanoparticle.
(2) Mix 400 ul of silane coupling agent (APTES) solution with 2 ml of deionized water. The mixed solution is then dropped dropwise into the above ZnO nanoparticle solution. After hydrolysis, APTES reacts with ZnO nanoparticle to form ZnO nanoparticle fully covered with silicon dioxide and precipitates. Centrifuge at 6000 r/min for 2 minutes, wash the precipitate twice with ethanol, and finally dissolve it in aqueous solution. That is, a clear aqueous solution of ZnO nanoparticle fully coated with silicon dioxide is obtained.

In addition to the above methods, other methods may also be used to prepare ZnO nanoparticle fully coated with silicon dioxide.
(3) Take an appropriate amount of chlorobenzene as the oil phase solution. The aqueous solution of ZnO nanoparticle fully coated with silicon dioxide is slowly poured into chlorobenzene to form a water-oil phase interface. After standing to form a stable interface, a small amount of ethanol is added to the water phase to precipitate a small amount of SiO2 fully-coated ZnO nanoparticle. The settled nanoparticle may float on a chlorobenzene liquid surface.
(4) Add lipophilic ligand to the oil phase solution in step (3) to bind to a lower half of the SiO2 fully-coated ZnO nanoparticle floating at an interface to stabilize the interface.
(5) Add appropriate amounts of hydrogen peroxide and hydrofluoric acid to the aqueous solution in step (4). After reaction for a period of time, SiO2 in the upper half of the fully coated ZnO nanoparticles floating at the interface may be etched away in the water phase. That is, silicon dioxide semi-coated ZnO nanoparticle are obtained.
(6) Separate the water phase and oil phase. Because the silicon dioxide semi-coated ZnO nanoparticle floating at the interface are fixed with lipophilic group, the nanoparticle with semi-coated characteristics may be screened out when the water phase is removed.
(7) In order to remove the silicon dioxide fully-coated ZnO nanoparticles that entered the oil phase in step (3), based on structural differences between silicon dioxide fully-coated ZnO nanoparticle and silicon dioxide semi-coated ZnO nanoparticle, a precipitant may be added for further screening, and finally pure silicon dioxide semi-coated ZnO nanoparticle may be obtained.

The selection of precipitant may be achieved by adjusting polarity and dosage according to the precipitation requirements of nanoparticle.

Embodiments of the present application further provide a nano-film including a zinc oxide nanoparticle and a silicon dioxide coating layer. At least part of a surface of the zinc oxide nanoparticle is partially coated with the silicon dioxide coating layer. A contact area between the silicon dioxide coating layer and the zinc oxide nanoparticle accounts for 30% to 70% of a surface area of the zinc oxide nanoparticle.

In some embodiments of the present application, oxygen atoms of the zinc oxide nanoparticle and oxygen atoms of silicon dioxide in the silicon dioxide coating layer are connected through covalent bonds.

In some embodiments of the present application, the zinc oxide nanoparticle comprises a zinc oxide material or a doped zinc oxide material, and a doping element of the doped zinc oxide material include, but are not limited to, Mg, Al or Ga. In the doped zinc oxide material, a molar ratio of the zinc oxide and the doping element is 1:(0.1˜0.3).

In some embodiments of the present application, a particle size range of the zinc oxide nanoparticle may be 3 nm to 5 nm, 3.5 nm to 4.5 nm, or 4 nm.

An embodiment of the present application also provides a light-emitting diode, including an anode, a cathode, and a light-emitting layer disposed between the anode and the cathode. An electron transport layer is also provided between the cathode and the light-emitting layer. A material of the electron transport layer includes the above-mentioned nano-film.

In some embodiments of the present application, a positive quantum dot light-emitting diode is provided. As shown in FIG. 4, from bottom to top are an anode 1, a hole injection layer 2, a hole transport layer 3, a quantum dot light-emitting layer 4, an electron transport layer 5, and a cathode 6. A material of the electron transport layer 5 includes the above-mentioned nano-film.

In some embodiments of the present application, a thickness of the electron transport layer 5 may be 10˜60 nm, 20˜50 nm, or 30˜40 nm. Both too thin and too thick film thicknesses are not conducive to the injection and transmission of carriers, thus, a thickness range of the electron transport layer needs to be within the above range.

In some embodiments of the present application, a material of the anode 1 may be indium tin oxide (ITO), indium zinc oxide, etc., or may also be metal, alloy, and compounds with various conductivity properties and their mixtures. For example, Au, Pt, Si, etc. may be used, preferably indium tin oxide (ITO).

In some embodiments of the present application, a material of the hole injection layer 2 may be water-soluble PEDOT:PSS (poly3,4-ethylenedioxythiophene/polystyrenesulfonate), may be other materials with good hole injection properties, such as NiO, MoO₃, WO₃ or V₂O₅, etc. PEDOT:PSS is preferred as the hole injection layer in this application.

In some embodiments of the present application, a thickness of the hole injection layer 2 may be 10˜100 nm, 20˜90 nm, or 30˜80 nm.

In some embodiments of the present application, a material of the hole transport layer 3 may be commonly used one or more of poly(9,9-dioctylfluorene-CO—N-(4-butylphenyl)diphenylamine) (TFB), polyvinyl carbazole (PVK), poly(N,N′bis(4-butylphenyl)-N,N′-bis(phenyl)benzidine) (Poly-TPD), poly(9,9-dioctylfluorene-co-bis-N,N-phenyl-1,4-phenylenediamine) (PFB), 4,4′,4″-Tris(carbazol-9-yl)triphenylamine (TCTA), 4,4′-bis(9-carbazole)biphenyl (CBP), N,N′-diphenyl-N,N′-bis(3-methylphenyl)-1,1′-biphenyl-4,4′-diamine (TPD), or N,N′-diphenyl-N,N′-(1-naphthyl)-1,1′-biphenyl-4,4′-diamine (NPB). Other high performance hole transport materials are also possible. For example, the material of the hole transport layer may be mixed with TFB and PVK at a mass ratio of 1:(1˜2). The material of the hole transport layer may also be mixed with TFB, PVK, and TCTA in a mass ratio of 1:(2˜4):(3˜8).

In some embodiments of the present application, the thickness of the hole transport layer 3 may be 1˜100 nm, 10˜90 nm, or 20˜80 nm.

In some embodiments of the present application, quantum dots in the quantum dot light-emitting layer 4 are one of red quantum dots, green quantum dots, and blue quantum dots. As an exemplary solution, the quantum dots in the quantum dot light-emitting layer are blue quantum dots. Quantum dots may be CdS, CdSe, CdTe, ZnO, ZnS, ZnSe, ZnTe, GaAs, GaP, GaSb, HgS, HgSe, HgTe, InAs, InP, InSb, AlAs, AlP, CuInS, CuInSe, and at least one of various core-shell structure quantum dots. The three colors of quantum dots may control the size of the nanocrystals through different relative contents of the same element or through different element compositions, thereby controlling the color.

In some embodiments of the present application, the thickness of the quantum dot light-emitting layer 4 may be 20˜60 nm, 30˜50 nm, or 40 nm.

In some embodiments of the present application, a material of the cathode 6 includes at least one of Al, Ag, Au, or Cu.

In some embodiments of the present application, the thickness of the cathode 6 may be 60˜120 nm, 70˜110 nm, or 60˜100 nm.

In some embodiments of the present application, the preparation method of a positive quantum dot light-emitting diode includes sequentially forming a hole injection layer 2, a hole transport layer 3, a quantum dot light-emitting layer 4, an electron transport layer 5, and a cathode 6 on the anode 1. The material of the electron transport layer 5 includes the above-mentioned nanoparticle.

In some embodiments of the present application, a preparation method of a positive quantum dot light-emitting diode includes the following:
(1) Form anode 1: A substrate with a bottom electrode is processed. The substrate may be a rigid substrate, such as glass, or a flexible substrate, such as PI. The bottom electrode is formed on the substrate, such as an ITO substrate. Then clean the patterned ITO substrate. Before depositing other functional layers, the clean ITO substrate is treated with UV-ozone or oxygen plasma to further remove organic matter attached to the ITO surface and improve a work function of ITO.
(2) Deposit a hole injection layer 2 on the surface of the processed substrate.
(3) Place the substrate in a nitrogen atmosphere, and deposit a hole transport layer 3 on the surface of the hole injection layer 2.
(4) Deposit a layer of quantum dot light-emitting layer 4 on the hole transport layer 3.
(5) Deposit another layer of nano-film as the electron transport layer 5.
(6) Form cathode 6: place it in an evaporation chamber and thermally evaporate a layer of top electrode through a mask.

An embodiment of the present application also provides an inverted quantum dot light-emitting diode, From bottom to top are a cathode, an electron transport layer, a quantum dot light-emitting layer, a hole transport layer, a hole injection layer, and an anode. A material of the electron transport layer includes the above-mentioned nano-film.

In some embodiments of the present application, the thickness of the electron transport layer may be 10˜60 nm, 20˜50 nm, or 30˜40 nm. Both too thin and too thick film thicknesses are not conducive to the injection and transmission of carriers, thus, the thickness range of the electron transport layer needs to be within the above range.

The material selection and thickness of other layers are the same as those of positive quantum dot light-emitting diodes, and will not be described again here.

In some embodiments of the present application, the preparation method of the inverted quantum dot light-emitting diode includes sequentially forming an electron transport layer, a quantum dot light-emitting layer, a hole transport layer, a hole injection layer, and an anode on the cathode. A material of the electron transport layer includes the above-mentioned nanoparticle.

In some embodiments of the present application, the preparation method for an inverted quantum dot light-emitting diode includes the following:
(1) Provide a substrate, where the substrate may be a rigid substrate, such as glass, or a flexible substrate, such as PI. A cathode is formed on the substrate.
(2) Deposit another layer of nano-film as an electron transport layer.
(3) Deposit a quantum dot light-emitting layer on the electron transport layer.
(4) Deposit a hole transport layer on the quantum dot light-emitting layer.
(5) Deposit a hole injection layer on the hole transport layer.
(6) Form an anode on the hole injection layer.

The present application will be described in detail through examples below.

### Embodiment 1

This embodiment provides a preparation method for nanoparticle including the following steps:
S1: Weigh 5.5 g zinc acetate dihydrate and dissolve it in 150 ml ethanol solution. Heat and stir at 80° C. for 2 hours until acetic acid is completely dissolved. Then place the above solution in a cold water bath. Take 20 ml of 1.75 mol/L potassium hydroxide solution and slowly pour the potassium hydroxide solution into the above solution. When the solution becomes clear, the preparation of ZnO nanoparticle is completed.
S2: Mix 400 ul of silane coupling agent (APTES) solution with 2 ml of deionized water. The mixed solution is then dropped dropwise into the solution obtained in S1. After hydrolysis, APTES reacts with ZnO nanoparticle to form ZnO nanoparticle fully covered with silicon dioxide and precipitates. Centrifuge at 6000 r/min for 2 minutes, wash the precipitate twice with ethanol, and finally dissolve it in aqueous solution. That is, a clear aqueous solution of ZnO nanoparticle fully coated with silicon dioxide is obtained.
S3: Take 50 ml of chlorobenzene as the oil phase solution and place it in a 200 ml beaker. Take 20 ml of the aqueous solution of ZnO nanoparticle fully coated with silicon dioxide and slowly pour it into chlorobenzene to form a water-oil phase interface. Let it stand for 2 hours. After a stable interface is formed, add 1 ml of 95% ethanol to the water phase to precipitate a small amount of SiO2 fully-coated ZnO nanoparticle. The settled nanoparticle may float on the chlorobenzene liquid surface.
S4: Add 5 ml of octadecene to the chlorobenzene solution in S3 and react for 10 minutes to combine with the lower half of the SiO2 fully-coated ZnO nanoparticles floating at the interface.
S5: Add 4 ml hydrogen peroxide and 1 ml hydrofluoric acid to the aqueous solution in S4 and react for 30 minutes. The SiO2 in the upper half of the SiO2 semi-coated ZnO nanoparticle floating at the interface may be etched away in the water phase. That is, silicon dioxide semi-coated ZnO nanoparticle is obtained.
S6: Remove the aqueous solution and add 10 ml of n-hexane to the remaining chlorobenzene solution. The resulting precipitate is pure silicon dioxide semi-coated ZnO nanoparticle.

### Embodiment 2

This embodiment provides a preparation method for nanoparticle including the following steps:
S1: Weigh 5.5 g zinc acetate dihydrate and dissolve it in 150 ml ethanol solution. Heat and stir at 80° C. for 2 hours until acetic acid is completely dissolved. Then place the above solution in a cold water bath. Take 20 ml of 1.75 mol/L potassium hydroxide solution and slowly pour the potassium hydroxide solution into the above solution. When the solution becomes clear, the preparation of ZnO nanoparticle is completed.
S2: Mix 400 ul of silane coupling agent (APTES) solution with 2 ml of deionized water. The mixed solution is then dropped dropwise into the solution obtained in S1. After hydrolysis, APTES reacts with ZnO nanoparticle to form ZnO nanoparticle fully covered with silicon dioxide and precipitates. Centrifuge at 6000 r/min for 2 minutes, wash the precipitate twice with ethanol, and finally dissolve it in aqueous solution. That is, a clear aqueous solution of ZnO nanoparticle fully coated with silicon dioxide is obtained.
S3: Take 50 ml of carbon tetrachloride as the oil phase solution and place it in a 200 ml beaker. Take 20 ml of the aqueous solution of ZnO nanoparticle fully coated with silicon dioxide and slowly pour it into carbon tetrachloride to form a water-oil phase interface. Let it stand for 2 hours. After a stable interface is formed, add 1 ml of 95% ethanol to the water phase to precipitate a small amount of SiO2 fully-coated ZnO nanoparticle. The settled nanoparticle may float on the carbon tetrachloride liquid surface.
S4: Add 5 ml of octadecene to the carbon tetrachloride solution in S3 and react for 10 minutes to combine with the lower half of the SiO2 fully-coated ZnO nanoparticles floating at the interface.
S5: Add 4 ml hydrogen peroxide and 1 ml hydrofluoric acid to the aqueous solution in S4 and react for 30 minutes. The SiO2 in the upper half of the SiO2 semi-coated ZnO nanoparticle floating at the interface may be etched away in the water phase. That is, silicon dioxide semi-coated ZnO nanoparticle is obtained.
S6: Remove the aqueous solution and add 10 ml of n-hexane to the remaining carbon tetrachloride solution. The resulting precipitate is pure silicon dioxide semi-coated ZnO nanoparticle.

### Embodiment 3

This embodiment provides a preparation method for nanoparticle including the following steps:
S1: Weigh 5.5 g zinc acetate dihydrate and dissolve it in 150 ml ethanol solution. Heat and stir at 80° C. for 2 hours until acetic acid is completely dissolved. Then place the above solution in a cold water bath. Take 20 ml of 1.75 mol/L potassium hydroxide solution and slowly pour the potassium hydroxide solution into the above solution. When the solution becomes clear, the preparation of ZnO nanoparticle is completed.
S2: Mix 400 ul of silane coupling agent (APTES) solution with 2 ml of deionized water. The mixed solution is then dropped dropwise into the solution obtained in S1. After hydrolysis, APTES reacts with ZnO nanoparticle to form ZnO nanoparticle fully covered with silicon dioxide and precipitates. Centrifuge at 6000 r/min for 2 minutes, wash the precipitate twice with ethanol, and finally dissolve it in aqueous solution. That is, a clear aqueous solution of ZnO nanoparticle fully coated with silicon dioxide is obtained.
S3: Take 50 ml of chlorobenzene as the oil phase solution and place it in a 200 ml beaker. Take 20 ml of the aqueous solution of ZnO nanoparticle fully coated with silicon dioxide and slowly pour it into chlorobenzene to form a water-oil phase interface. Let it stand for 2 hours. After a stable interface is formed, add 1 ml of 95% ethanol to the water phase to precipitate a small amount of SiO2 fully-coated ZnO nanoparticle. The settled nanoparticle may float on the chlorobenzene liquid surface.
S4: Add 5 ml of n-octylamine to the chlorobenzene solution in S3 and react for 3 minutes to combine with the lower half of the SiO2 fully-coated ZnO nanoparticles floating at the interface.
S5: Add 4 ml hydrogen peroxide and 1 ml hydrofluoric acid to the aqueous solution in S4 and react for 30 minutes. The SiO2 in the upper half of the SiO2 semi-coated ZnO nanoparticle floating at the interface may be etched away in the water phase. That is, silicon dioxide semi-coated ZnO nanoparticle is obtained.
S6: Remove the aqueous solution and add 10 ml of n-hexane to the remaining chlorobenzene solution. The resulting precipitate is pure silicon dioxide semi-coated ZnO nanoparticle.

### Embodiment 4

This embodiment provides a preparation method for nanoparticle including the following steps:
S1: Weigh 5.5 g zinc acetate dihydrate and dissolve it in 150 ml ethanol solution. Heat and stir at 80° C. for 2 hours until acetic acid is completely dissolved. Then place the above solution in a cold water bath. Take 20 ml of 1.75 mol/L potassium hydroxide solution and slowly pour the potassium hydroxide solution into the above solution. When the solution becomes clear, the preparation of ZnO nanoparticle is completed.
S2: Mix 400 ul of silane coupling agent (APTES) solution with 2 ml of deionized water. The mixed solution is then dropped dropwise into the solution obtained in S1. After hydrolysis, APTES reacts with ZnO nanoparticle to form ZnO nanoparticle fully covered with silicon dioxide and precipitates. Centrifuge at 6000 r/min for 2 minutes, wash the precipitate twice with ethanol, and finally dissolve it in aqueous solution. That is, a clear aqueous solution of ZnO nanoparticle fully coated with silicon dioxide is obtained.
S3: Take 50 ml of chlorobenzene as the oil phase solution and place it in a 200 ml beaker. Take 20 ml of the aqueous solution of ZnO nanoparticle fully coated with silicon dioxide and slowly pour it into chlorobenzene to form a water-oil phase interface. Let it stand for 2 hours. After a stable interface is formed, add 1 ml of 95% ethanol to the water phase to precipitate a small amount of SiO2 fully-coated ZnO nanoparticle. The settled nanoparticle may float on the chlorobenzene liquid surface.
S4: Add 5 ml of octadecene to the chlorobenzene solution in S3 and react for 10 minutes to combine with the lower half of the SiO2 fully-coated ZnO nanoparticles floating at the interface.
S5: Add 8 ml hydrogen peroxide and 1 ml hydrofluoric acid to the aqueous solution in S4 and react for 20 minutes. The SiO2 in the upper half of the SiO2 semi-coated ZnO nanoparticle floating at the interface may be etched away in the water phase. That is, silicon dioxide semi-coated ZnO nanoparticle is obtained.
S6: Remove the aqueous solution and add 10 ml of n-hexane to the remaining chlorobenzene solution. The resulting precipitate is pure silicon dioxide semi-coated ZnO nanoparticle.

### Embodiment 5

This embodiment provides a preparation method for nanoparticle including the following steps:
S1: Weigh 5.5 g zinc acetate dihydrate and dissolve it in 150 ml ethanol solution. Heat and stir at 80° C. for 2 hours until acetic acid is completely dissolved. Then place the above solution in a cold water bath. Take 20 ml of 1.75 mol/L potassium hydroxide solution and slowly pour the potassium hydroxide solution into the above solution. When the solution becomes clear, the preparation of ZnO nanoparticle is completed.
S2: Mix 400 ul of silane coupling agent (APTES) solution with 2 ml of deionized water. The mixed solution is then dropped dropwise into the solution obtained in S1. After hydrolysis, APTES reacts with ZnO nanoparticle to form ZnO nanoparticle fully covered with silicon dioxide and precipitates. Centrifuge at 6000 r/min for 2 minutes, wash the precipitate twice with ethanol, and finally dissolve it in aqueous solution. That is, a clear aqueous solution of ZnO nanoparticle fully coated with silicon dioxide is obtained.
S3: Take 50 ml of chlorobenzene as the oil phase solution and place it in a 200 ml beaker. Take 20 ml of the aqueous solution of ZnO nanoparticle fully coated with silicon dioxide and slowly pour it into chlorobenzene to form a water-oil phase interface. Let it stand for 2 hours. After a stable interface is formed, add 1 ml of 95% ethanol to the water phase to precipitate a small amount of SiO2 fully-coated ZnO nanoparticle. The settled nanoparticle may float on the chlorobenzene liquid surface.
S4: Add 5 ml of octadecene to the chlorobenzene solution in S3 and react for 10 minutes to combine with the lower half of the SiO2 fully-coated ZnO nanoparticles floating at the interface.
S5: Add 4 ml hydrogen peroxide and 1 ml hydrofluoric acid to the aqueous solution in S4 and react for 30 minutes. The SiO2 in the upper half of the SiO2 semi-coated ZnO nanoparticle floating at the interface may be etched away in the water phase. That is, silicon dioxide semi-coated ZnO nanoparticle is obtained.
S6: Remove the aqueous solution and add 20 ml of n-heptane to the remaining chlorobenzene solution. The resulting precipitate is pure silicon dioxide semi-coated ZnO nanoparticle.

### Embodiment 6

This embodiment provides a preparation method for a quantum dot light-emitting diode provided in this embodiment includes the following steps:
(1) Preparation of an anode layer: A patterned ITO substrate is placed in an acetone, a washing solution, a deionized water, and an isopropyl alcohol in order for ultrasonic cleaning. Each of the above steps of ultrasound needs to last about 15 minutes. After the ultrasound is completed, place the ITO in a clean oven to dry and set aside. After the ITO substrate is dried, the ITO surface is treated with UV ozone for 5 minutes to further remove organic matter attached to the ITO surface and improve a work function of ITO.
(2) Preparation of a hole injection layer: A layer of PEDOT:PSS is deposited on a surface of the treated ITO substrate with a thickness of 30 nm. Place the substrate on a heating platform at 150° C. for 30 minutes to remove moisture. This step needs to be completed in the air.
(3) Preparation of a hole transport layer: The dried substrate coated with the hole injection layer is placed in a nitrogen atmosphere. Deposit a layer of hole transport layer material TFB to a thickness of 30 nm. Place the substrate on a heating platform at 150° C. and heat for 30 minutes to remove the solvent.
(4) Preparation of a quantum dot light-emitting layer: After a chip processed in the previous step is cooled, a blue quantum dot light-emitting material is spin-coated on the surface of the hole transport layer with a thickness of 20 nm. After the deposition of this step is completed, place the film on a heating table at 80° C. for 10 minutes to remove the remaining solvent.
(5) Preparation of an electron transport layer: Nanoparticle (prepared by the method of Embodiment 1) is spin-coated on the quantum dot layer to obtain a nano-film as the electron transport layer, with a thickness of 30 nm. After the deposition is completed, place the chip on a heating table at 80° C. for 30 minutes.
(6) Preparation of a cathode layer: Place the chip with each functional layer deposited in an evaporation chamber and thermally evaporate a layer of aluminum through a mask as the cathode, with a thickness of 100 nm. The quantum dot light-emitting diode device is prepared.

This application prepares zinc oxide nanoparticle partially coated with silicon dioxide. The zinc oxide nanoparticle partially coated with a silicon dioxide coating layer may reduce interaction at the interface of different materials, thereby improving material performance stability and conductivity. Usually, due to different materials, the conductivity and active transition of the film layers used to prepare the device are too different, and they may even react and deteriorate with each other, which may lead to some losses in performance. The zinc oxide nanoparticle partially coated with silicon dioxide and having an asymmetric electronic structure introduced in the present application may play a good buffering role. As an electron transport layer material, it improves stability and efficiency of the quantum dot light-emitting diode.

The above is a detailed introduction to a nanoparticle, a preparation method therefor, and a light-emitting diode provided in embodiments of the present application. This article uses specific examples to illustrate the principles and implementation methods of the present application. The description of the above embodiments is only used to help understand the technical solutions and core ideas of the present application. Those of ordinary skill in the art should understand that they may still modify the technical solutions described in the foregoing embodiments, or make equivalent substitutions for some of the technical features. However, these modifications or substitutions do not cause the essence of the corresponding technical solutions to depart from the scope of the technical solutions of the embodiments of the present application.

1. A nanoparticle, comprising:
a zinc oxide nanoparticle and a silicon dioxide coating layer, wherein a surface of the zinc oxide nanoparticle is partially covered with the silicon dioxide coating layer.

2. The nanoparticle according to claim 1, wherein a contact area between the silicon dioxide coating layer and the zinc oxide nanoparticle accounts for 30% to 70% of a surface area of the zinc oxide nanoparticle.

3. The nanoparticle according to claim 1, wherein oxygen atoms of the zinc oxide nanoparticle and oxygen atoms of silicon dioxide in the silicon dioxide coating layer are connected through covalent bonds.

4. The nanoparticle according to claim 1, wherein the zinc oxide nanoparticle comprises a zinc oxide material or a doped zinc oxide material, and a doping element of the doped zinc oxide material comprises any one of Mg, Al, and Ga.

5. The nanoparticle according to claim 4, wherein in the doped zinc oxide material, a molar ratio of the zinc oxide and the doping element is 1:(0.1˜0.3).

6. The nanoparticle according to claim 1, wherein a particle size of the zinc oxide nanoparticle ranges from 3 nm to 5 nm.

7. A preparation method for a nanoparticle, comprising:
providing a nanoparticle having a zinc oxide nanoparticle core and a silicon dioxide coating layer;
suspending the nanoparticle having the zinc oxide nanoparticle core and the silicon dioxide coating layer at a junction of an aqueous solution and an oil phase solution;
adding an acid etching solution to the aqueous solution, and acid etching to remove the silicon dioxide coating layer in the nanoparticle that is in contact with the aqueous solution to obtain the nanoparticle.

8. The preparation method for the nanoparticle according to claim 7, further comprising: suspending the nanoparticle having the zinc oxide nanoparticle core and the silicon dioxide coating layer at the junction of an aqueous phase solution and the oil phase solution, and adding a lipophilic ligand to the oil phase solution.

9. The preparation method for the nanoparticle according to claim 8, wherein the lipophilic ligand contains a lipophilic group, and the lipophilic group comprises any one of a hydrocarbon group having 10 to 20 carbon atoms, a hydrocarbon group containing an aryl, an ester, an ether, an amine, and an amide group, a hydrocarbon group containing double bonds, a polyoxypropylene group, a long-chain perfluoroalkyl group, and a polysiloxane group.

10. The preparation method for the nanoparticle according to claim 9, wherein a carbon chain length of the polyoxypropylene group is 6 to 18;
a carbon chain length of the long-chain perfluoroalkyl group is 6 to 18; and
a carbon chain length of the polysiloxane group is 6 to 18.

11. The preparation method for the nanoparticle according to claim 8, wherein the lipophilic ligand comprises a n-octylamine or an octadecene.

12. The preparation method for the nanoparticle according to claim 7, wherein the acid etching solution comprises a hydrogen peroxide and a hydrofluoric acid; and
a density of the oil phase solution is greater than a density of the aqueous phase solution, and the oil phase solution comprises any one of a chlorobenzene, a nitrobenzene, a chloroform, a carbon tetrachloride, a carbon disulfide, a dimethyl sulfoxide, and a methylene chloride.

13. The preparation method for the nanoparticle according to claim 7, wherein after acid etching to remove the silicon dioxide coating layer in the nanoparticle that is in contact with the aqueous solution, the preparation method for the nanoparticle further comprises: removing the aqueous solution, adding a precipitant for purification, and obtaining the nanoparticle; wherein the precipitant comprises one or more of a n-hexane and a n-heptane.

14. A light-emitting diode, comprising:
an anode, a cathode, and a light-emitting layer arranged between the anode and the cathode, wherein an electron transport layer is further provided between the cathode and the light-emitting layer, a material of the electron transport layer comprises a nano-film, the nano-film comprises a zinc oxide nanoparticle and a silicon dioxide coating layer, and at least part of a surface of the zinc oxide nanoparticle is partially coated with the silicon dioxide coating layer.

15. The light-emitting diode according to claim 14, wherein a contact area between the silicon dioxide coating layer and the zinc oxide nanoparticle accounts for 30% to 70% of a surface area of the zinc oxide nanoparticle.

16. The light-emitting diode according to claim 14, wherein oxygen atoms of the zinc oxide nanoparticle and oxygen atoms of silicon dioxide in the silicon dioxide coating layer are connected through covalent bonds.

17. The light-emitting diode according to claim 14, wherein the zinc oxide nanoparticle comprises a zinc oxide material or a doped zinc oxide material, and a doping element of the doped zinc oxide material comprises any one of Mg, Al, and Ga.

18. The light-emitting diode according to claim 14, wherein a particle size of the zinc oxide nanoparticle ranges from 3 nm to 5 nm.

19. The light-emitting diode according to claim 14, wherein a thickness of the electron transport layer is 10 nm to 60 nm.

20. The light-emitting diode according to claim 14, wherein a light-emitting layer is a quantum dot light-emitting layer, a quantum dot material of the quantum dot light-emitting layer is selected from one or more combinations of CdS, CdSe, CdTe, ZnO, ZnS, ZnSe, ZnTe, GaAs, GaP, GaSb, HgS, HgSe, HgTe, InAs, InP, InSb, AlAs, AlP, CuInS, or CuInSe;
a material of the anode comprises one or more of an indium tin oxide, an indium zinc oxide, Au, Pt, or Si;
a material of the cathode comprises one or more of Al, Ag, Au, or Cu;
the light-emitting diode further comprises a hole injection layer and a hole transport layer provided between the light-emitting layer and the anode, the hole injection layer is located between the hole transport layer and the anode; a material of the hole injection layer is selected from one or more of PEDOT:PSS, NiO, MoO₃, WO₃, and V₂O₅; and
a material of the hole transport layer is selected from one or more of poly(9,9-dioctylfluorene-CO—N-(4-butylphenyl)diphenylamine), polyvinylcarbazole, poly(N,N′bis(4-butylphenyl)-N,N′-bis(phenyl)benzidine), poly(9,9-dioctylfluorene-co-bis-N,N-phenyl 1,4-phenylenediamine), 4,4′,4″-tris(carbazol-9-yl)triphenylamine, 4,4′-bis(9-carbazole)biphenyl, N,N′-diphenyl-N,N′-bis(3-methylphenyl)-1,1′-biphenyl-4,4′-diamine, N,N′-diphenyl-N,N′-(1-naphthyl)-1,1′-biphenyl-4,4′-diamine.
